(19) United States
(12) Patent Application Publication
(10) Pub. No.: US 2025/0212396 A1
(43) Pub. Date: Jun. 26, 2025

(54) SEMICONDUCTOR DEVICE

(71) Applicant: SAMSUNG ELECTRONICS CO., LTD., Suwon-si (KR)

(72) Inventor: Hyungki Cho, Suwon-si (KR)

(21) Appl. No.: 18/893,322

(22) Filed: Sep. 23, 2024

(30) Foreign Application Priority Data
Dec. 21, 2023 (KR) 10-2023-0188380

(51) Int. Cl. H10B 12/00

(52) U.S. Cl. CPC H10B 12/488; H10B 12/315; H10B 12/482

(57) ABSTRACT

A semiconductor device includes a bit line extending in a first direction on a substrate, first and second word lines extending in a second direction on the bit line, crossing the bit line, and spaced from each other in the first direction, and semiconductor patterns on the bit line spaced from each other in the first direction with the first and second word lines interposed therebetween, wherein the first word line includes a first portion and second portions protruding from the first portion and spaced apart from each other in the second direction, the second word line includes a first portion and second portions protruding in a direction, and one of the semiconductor patterns is interposed between the second portions of the first word line, and another one of the semiconductor patterns is interposed between the second portions of the second word line.

### CROSS-REFERENCE TO RELATED APPLICATION

This U.S. non-provisional patent application claims priority under 35 U.S.C. § 119 to Korean Patent Application No. 10-2023-0188380 filed on Dec. 21, 2023, in the Korean Intellectual Property Office, the entire contents of which are hereby incorporated by reference.

### BACKGROUND

The present disclosure relates to a semiconductor device, and more particularly, relates to a semiconductor device including vertical channel transistors.

As semiconductor device sizes are scaled down, fabrication technology capable of increasing an integration density of a semiconductor device and improving an operation speed and a production yield is in demand. Vertical channel transistors can increase an integration density of a semiconductor device and improve resistance and current driving characteristics of the transistor.

### SUMMARY

The present disclosure provides a semiconductor device with improved electrical characteristics in an oxide semiconductor device having a vertical channel structure.

In a general aspect, a semiconductor device includes: a substrate, a bit line extending in a first direction on the substrate, a first word line and a second word line extending in a second direction on the bit line, crossing the bit line, and spaced apart from each other in the first direction, the first direction and the second direction parallel to an upper surface of the substrate and intersecting each other, and semiconductor patterns on the bit line spaced apart from each other in the first direction with the first and second word lines interposed therebetween, wherein the first word line includes a first portion extending in the second direction and second portions protruding from the first portion in the first direction and spaced apart from each other in the second direction, the second word line includes a first portion extending in the second direction and second portions protruding in a direction opposite to the first direction, and one of the semiconductor patterns is interposed between the second portions of the first word line, and another one of the semiconductor patterns is interposed between the second portions of the second word line.

In another general aspect, a semiconductor device includes: a substrate, bit lines extending in a first direction on the substrate and spaced apart from each other in a second direction, the first direction and the second direction being parallel to an upper surface of the substrate and intersecting each other, a first word line crossing the bit lines and including a first portion extending in the second direction and a second portion protruding from the first portion in the first direction and spaced apart from each other in the second direction, and semiconductor patterns respectively disposed on the bit lines, wherein each of the semiconductor patterns includes a first vertical portion extending in a direction perpendicular to the upper surface of the substrate, the first vertical portions of the semiconductor patterns are interposed between the second portions of the first word line, and the second portions of the first word line and the first vertical portions of the semiconductor patterns are alternately arranged in the second direction.

In another general aspect, a semiconductor device includes: a substrate, a bit line extending in a first direction on the substrate, a support insulating layer on the bit line, a first word line and a second word line crossing the bit line on the support insulating layer, semiconductor patterns disposed on the bit line and spaced apart from each other in the first direction with the support insulating layer and the first and second word lines interposed therebetween, a first gate insulating layer between one of the semiconductor patterns and an outer wall of the first word line, and a second gate insulating layer between another one of the semiconductor patterns and an outer wall of the second word line, wherein the first word line includes a first portion extending in a second direction parallel to an upper surface of the substrate and intersecting the first direction, and second portions protruding in the first direction, the second word line includes a first portion extending in the second direction and second portions protruding in a direction opposite to the first direction, the one of the semiconductor patterns is disposed between second portions of the first word line, and the another one of the semiconductor patterns is disposed between second portions of the second word line.

### BRIEF DESCRIPTION OF THE DRAWINGS

FIG. 1 is a block diagram of an example of a semiconductor device.

FIGS. 2 and 3 are schematic perspective views of examples of semiconductor devices.

FIG. 4 is a plan view of an example of a semiconductor device.

FIG. 5A is a cross-sectional view taken along line A-A′ of FIG. 4.

FIG. 5B is a cross-sectional view taken along line B-B′ of FIG. 4.

FIG. 5C is a cross-sectional view taken along line C-C′ of FIG. 4.

FIGS. 6 to 21C are views for explaining an example of a method of manufacturing a semiconductor device.

FIGS. 22 to 28 are cross-sectional views of examples of semiconductor devices.

### DETAILED DESCRIPTION

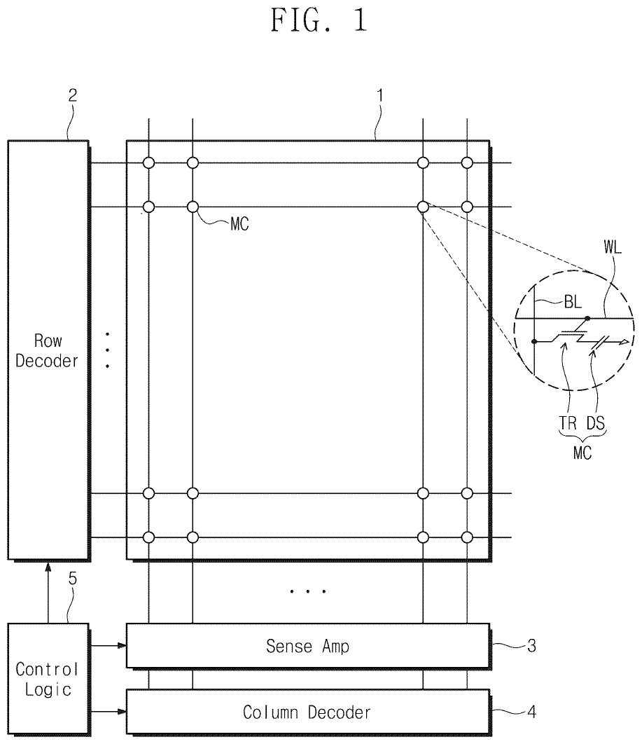

FIG. 1 is a block diagram of an example of a semiconductor device.

Referring to FIG. 1, a semiconductor memory device includes a memory cell array 1, a row decoder 2, a sense amplifier 3, a column decoder 4, and a control logic 5.

The memory cell array 1 may include a plurality of memory cells MC, which are two-dimensionally or three-dimensionally arranged. Each of the memory cells MC may be provided between and connected to a word line WL and a bit line BL, which are disposed to cross each other.

Each of the memory cells MC may include a selection element TR and a data storage element DS. The selection element TR and the data storage element DS may be electrically connected to each other. The selection element TR may be connected to both the word line WL and the bit line BL. That is, the selection element TR may be provided at a point where the word line WL and the bit line BL intersect each other.

The selection element TR may include a field effect transistor FET. The data storage element DS may include a capacitor, a magnetic tunnel junction pattern, or a variable resistor. As an example, the selection element TR may include a transistor whose gate electrode is connected to the word line WL and whose drain/source terminals are connected to the bit line BL and the data storage element DS, respectively.

The row decoder 2 may be configured to decode address information, which is input from the outside, and to select one of the word lines WL of the memory cell array 1, based on the decoded address information. The address information decoded by the row decoder 2 may be provided to a row driver, and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may provide a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data writing or reading operations on the memory cell array 1.

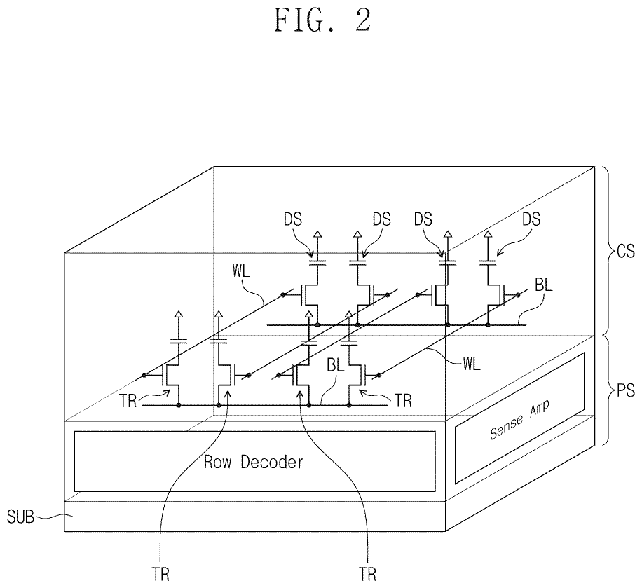

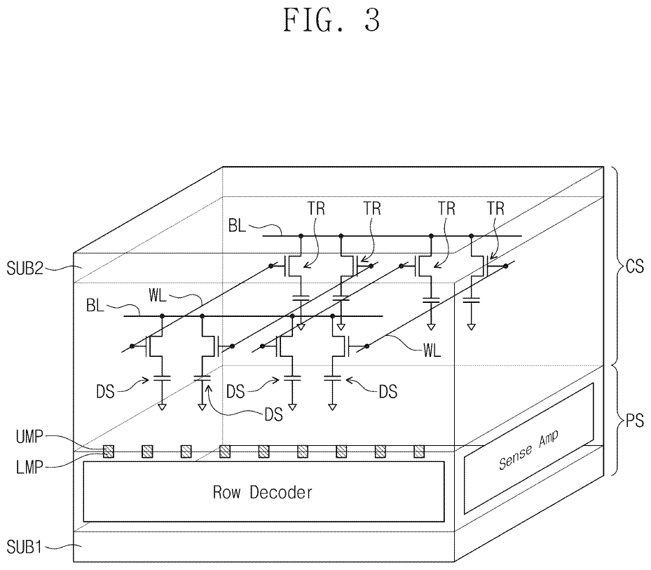

FIGS. 2 and 3 are schematic perspective views of semiconductor devices.

Referring to FIGS. 2 and 3, a semiconductor memory device may include a peripheral circuit structure PS on a semiconductor substrate and a cell array structure CS on the peripheral circuit structure PS.

The peripheral circuit structure PS may include core and peripheral circuits, which are formed on the substrate 100. The core and peripheral circuits may include the row and column decoders 2 and 4, the sense amplifier 3, and the control logics 5 described with reference to FIG. 1.

The cell array structure CS may include the memory cell array 1 (e.g., see FIG. 1) including the memory cells MC (e.g., see FIG. 1), which are two- or three-dimensionally arranged on a plane parallel to two different directions (e.g., first and second directions D1 and D2). Each of the memory cells MC (e.g., see FIG. 1) may include the selection element TR and the data storage device DS, as described above.

In some implementations, a vertical channel transistor (VCT) may be provided as the selection element TR of each memory cell MC (e.g., see FIG. 1). The vertical channel transistor may include a channel whose lengthwise direction is perpendicular to an upper surface of the substrate 100. A capacitor may be provided as the data storage device DS of each memory cell MC (e.g., see FIG. 1).

In the example of FIG. 2, the peripheral circuit structure PS may be provided on the substrate 100, and the cell array structure CS may be provided on the peripheral circuit structure PS.

In the example of FIG. 3, the peripheral circuit structure PS may be provided on a first substrate SUB1, and the cell array structure CS may be provided on a second substrate SUB2. The first substrate SUB1 and the second substrate SUB2 may face each other.

First metal pads LMP may be provided at the uppermost portion of the peripheral circuit structure PS. The first metal pads LMP may be electrically connected to the core and peripheral circuits 2, 3, 4, and 5 (e.g., in FIG. 1).

Second metal pads UMP may be provided at the lowermost portion of the cell array structure CS. The second metal pads UMP may be electrically connected to the memory cell array 1 (e.g., in FIG. 1). The second metal pads UMP may be in direct contact with and bond to the first metal pads LMP of the peripheral circuit structure PS.

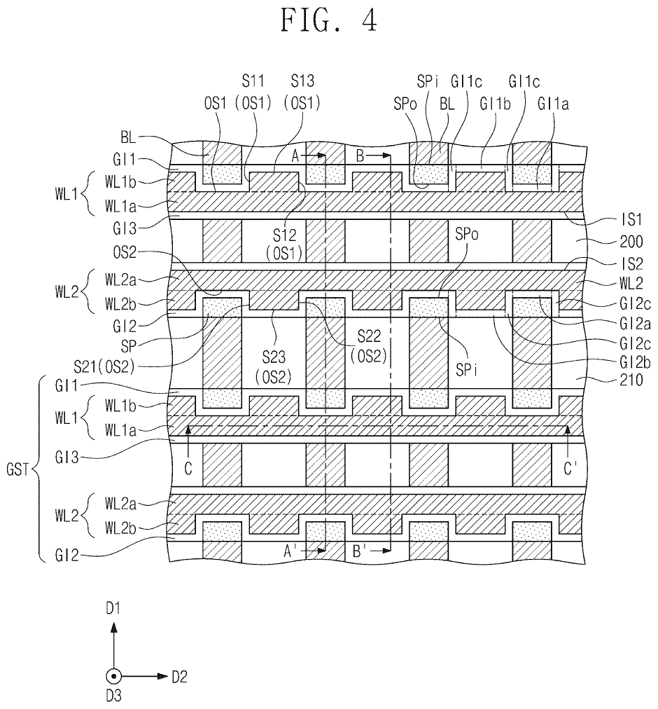

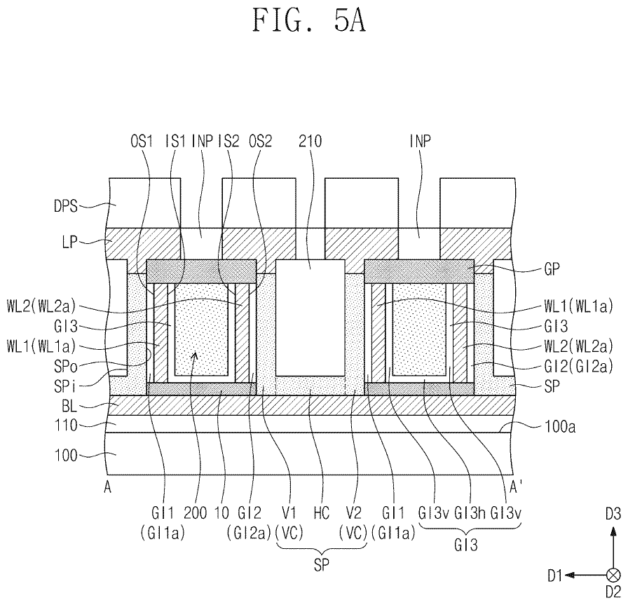

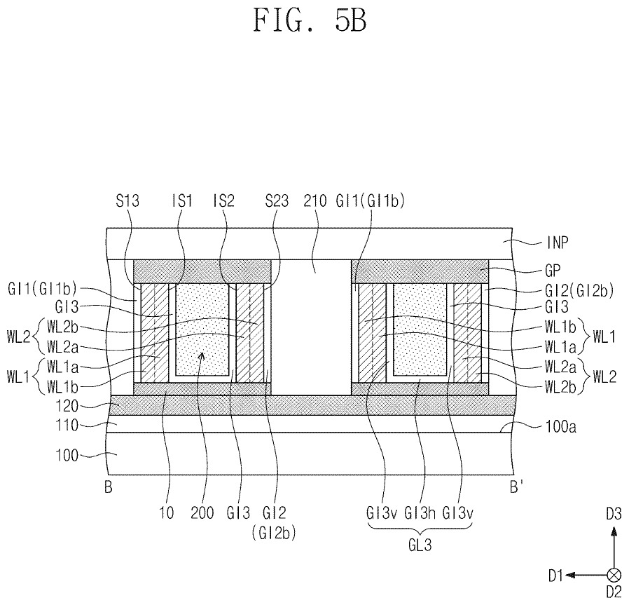

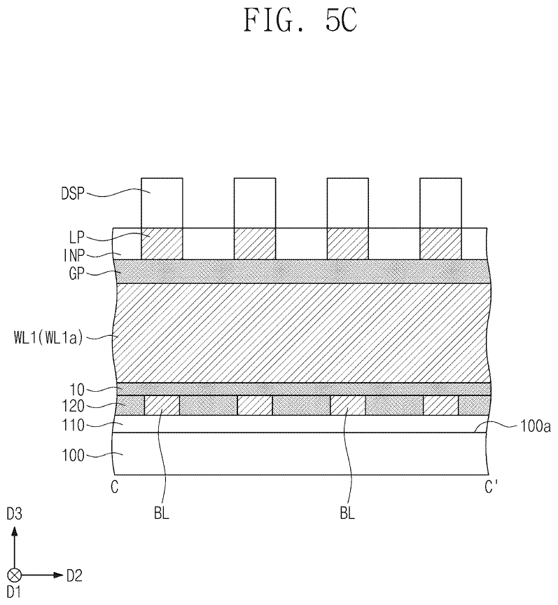

FIG. 4 is a plan view of an example of a semiconductor device. FIG. 5A is a cross-sectional view taken along line A-A′ of FIG. 4. FIG. 5B is a cross-sectional view taken along line B-B′ of FIG. 4. FIG. 5C is a cross-sectional view taken along line C-C′ of FIG. 4.

Referring to FIGS. 4 and 5A to 5C, a first lower insulating layer 110 is provided on a substrate 100. The substrate 100 may have a shape of a plate extending along a plane defined by a first direction D1 and a second direction D2. In this specification, the first direction D1 and the second direction D2 may be directions parallel to an upper surface 100a of the substrate 100 and intersecting each other. A third direction D3 may be a direction perpendicular to the upper surface 100a of the substrate 100. For example, the first direction D1, the second direction D2, and the third direction D3 may be directions orthogonal to each other. The substrate 100 may be a semiconductor substrate (e.g., a silicon substrate, a germanium substrate, and/or a silicon-germanium substrate). The first lower insulating layer 110 may include an insulating material. As an example, the first lower insulating layer 110 may include silicon oxide, silicon nitride, and/or silicon oxynitride.

In some implementations, the peripheral circuit structure PS described with reference to FIG. 2 may be provided between the substrate 100 and the first lower insulating layer 110. In some implementations, an integrated circuit such as a logic element may be provided between the substrate 100 and the first lower insulating layer 110.

A second lower insulating layer 120 may be provided on the first lower insulating layer 110. A plurality of bit lines BL may be provided in the second lower insulating layer 120. The bit lines BL may extend in the first direction D1 and be spaced apart from each other in the second direction D2.

The bit lines BL may include a conductive material. As an example, the bit lines BL may be formed of a doped semiconductor material (e.g., doped silicon, doped germanium, etc.), a conductive metal nitride (e.g., titanium nitride, tantalum nitride, etc.), a metal (e.g., tungsten, titanium, tantalum, etc.), and a metal-semiconductor compound (e.g., tungsten silicide, cobalt silicide, titanium silicide, etc.). The bit line BL may be a single conductive layer or multiple conductive layers. The second lower insulating layer 120 may include an insulating material. As an example, the second lower insulating layer 120 may include silicon oxide, silicon nitride, and/or silicon oxynitride.

Semiconductor patterns SP may be disposed on the bit lines BL. The semiconductor patterns SP may be disposed to be spaced apart from each other in the first and second directions D1 and D2. A plurality of semiconductor patterns SP may be disposed on one bit line BL. The plurality of semiconductor patterns SP disposed on one bit line BL may be arranged in the first direction D1. The semiconductor patterns SP may be respectively disposed on the plurality of bit lines BL spaced apart from each other in the second direction D2. The semiconductor patterns SP disposed on each of the plurality of bit lines BL may be arranged in the second direction D2.

The semiconductor pattern SP may include horizontal portions HC and vertical portions VC. The horizontal portion HC may be disposed on an upper surface of the bit line BL. The horizontal portion HC may extend in the first direction D1. The vertical portions VC may have a first vertical portion V1 and a second vertical portion V2 facing each other in the first direction D1. The horizontal portion HC may be adjacent to a lower portion of the first and second vertical portions V1 and V2 and connect the first and second vertical portions V1 and V2. The vertical portions VC may extend in a direction perpendicular to the upper surface 100a of the substrate 100 (e.g., the third direction D3).

Each of the vertical portions VC of the semiconductor pattern SP may include an inner wall SPi and an outer wall SPo facing each other in the first direction D1. The inner walls SPi of the vertical portions VC may face each other. The horizontal portion HC of the semiconductor pattern SP may be adjacent to the lower portion of the first and second vertical portions V1 and V2 and may connect the inner walls SPi of the first and second vertical portions V1 and V2.

The semiconductor pattern SP may include a semiconductor material. As an example, the semiconductor pattern SP may include an oxide semiconductor material, and the oxide semiconductor material may include at least one of, for example, InGaZnO, InGaSiO, InSnZnO, InZnO, ZnO, ZnSnO, ZnON, ZrZnSnO, SnO, HfInZnO, GaZnSnO, AlZnSnO, YbGaZnO, or InGaO. In some implementations, the semiconductor pattern SP may be a multi-layer including a plurality of material layers. In some implementations, the semiconductor pattern SP may include a two-dimensional material.

A gate structure GST may be disposed on the bit lines BL and the second lower insulating layer 120. A plurality of gate structures GST may be provided. The gate structures GST may extend in the second direction D2. The gate structures GST may be arranged to be spaced apart from each other in the first direction D1. The semiconductor patterns SP may be arranged to be spaced apart from each other in the second direction D2 between gate structures GST adjacent to each other in the first direction D1. The semiconductor patterns SP adjacent to each other in the first direction D1 may be spaced apart from each other with the gate structure GST interposed therebetween.

Each of the gate structures GST may include a support insulating layer 10, a first word line WL1, a second word line WL2, a first gate insulating layer GI1, a second gate insulating layer GI2, a third gate insulating layer GI3, and a gate capping layer GP.

The support insulating layer 10 may be disposed on the bit line BL and may be in contact with an upper surface of the bit line BL. The support insulating layer 10 may extend in the second direction D2. A lower surface of the support insulating layer 10 may be coplanar with a lower surface of the horizontal portion HC of the semiconductor pattern SP. The horizontal portions HC of the semiconductor patterns SP may be disposed between the support insulating layers 10 adjacent to each other in the first direction D1. The support insulating layer 10 may include an insulating material. The support insulating layer 10 may include, for example, silicon oxide, silicon nitride, and/or silicon oxynitride.

The first word line WL1 and the second word line WL2 may be disposed on the support insulating layer 10. Lower surfaces of the first word line WL1 and the second word line WL2 may be in contact with an upper surface of the support insulating layer 10. The first word line WL1 and the second word line WL2 may be spaced apart from each other in the first direction D1. The first word line WL1 and the second word line WL2 may extend in the second direction D2 and may cross the bit line BL.

The first word line WL1 may include a first portion WL1a that extends in the second direction D2 and second portions WL1b that protrude from the first portion WL1a in the first direction D1 and are spaced apart from each other in the second direction D2. The second word line WL2 may include a first portion WL2a that extends in the second direction D2 and second portions WL2b that protrude from the first portion WL2a in a direction opposite to the first direction D1 and are spaced apart from each other in the second direction D2.

Each of the second portions WL1b of the first word line WL1 may include a first sidewall S11 and a second sidewall S12 facing each other in the second direction D2, and a third sidewall S13 extending in the second direction D2 between the first sidewall S11 and the second sidewall S12. Each of the second portions WL2b of the second word line WL2 may include a first sidewall S21 and a second sidewall S22 facing each other in the second direction D2, and a third sidewall S23 extending in the second direction D2 between the first sidewall S21 and the second sidewall S22.

Each first vertical portion V1 of the semiconductor patterns SP may be disposed between the second portions WL1b of the first word line WL1. Specifically, the first vertical portions V1 of the semiconductor patterns SP disposed on the plurality of bit lines BL spaced apart from each other in the second direction D2 may be disposed between the second portions WL1b of the first word line WL1, respectively. The first vertical portions V1 of each of the semiconductor patterns SP and the second portions WL1b of the first word line WL1 may be alternately arranged in the second direction D2. The third sidewalls S13 of the second portions WL1b of the first word line WL1 and outer sidewalls SPo of each of the first vertical portions V1 of the semiconductor patterns SP may be offset from each other in the first direction D1. The first vertical portion V1 of the semiconductor pattern SP may be interposed between the second portions WL1b of the first word line WL1 that are adjacent to each other in the second direction D2. When viewed in a plan view, the third sidewalls S13 of the second portions WL1b of the first word line WL1 and the outer wall SPo of each of the first vertical portions V1 of the semiconductor patterns SP may be arranged in a zigzag shape in the second direction D2.

Each second vertical portion V2 of the semiconductor patterns SP may be disposed between the second portions WL2b of the second word line WL2. Specifically, the second vertical portions V2 of the semiconductor patterns SP respectively disposed on the plurality of bit lines BL spaced apart from each other in the second direction D2 may be disposed between the second portions WL2b of the second word line WL2, respectively. The second vertical portions V2 of each of the semiconductor patterns SP and the second portions WL2b of the second word line WL2 may be alternately arranged in the second direction D2. The third sidewalls S23 of the second portions WL2b of the second word line WL2 and outer sidewalls SPo of each of the second vertical portions V2 of the semiconductor patterns SP may be offset from each other in the first direction D1. The second vertical portion V2 of the semiconductor pattern SP may be interposed between the second portions WL2b of the second word line WL2 that are adjacent to each other in the second direction D2. When viewed in a plan view, the third sidewalls S23 of the second portions WL2b of the second word line WL2 and the outer wall SPo of each of the second vertical portions V2 of the semiconductor patterns SP may be arranged in a zigzag shape in the second direction D2.

The gate structure GST may be disposed between the semiconductor patterns SP adjacent to each other in the first direction D1. Specifically, the semiconductor patterns SP disposed on one bit line BL and adjacent to each other in the first direction D1 may be spaced apart from each other in the first direction with the support insulating layer 10, the first word line WL1, the second word line WL2, the first gate insulating layer GI1, the second gate insulating layer GI2, the third gate insulating layer GI3, and the gate capping layer GP interposed therebetween. For example, one of the semiconductor patterns SP may be disposed between the second portions WL1b of the first word line WL1, and another of the semiconductor patterns SP may be disposed between the second portions WL2b of the second word line WL2. The first vertical portion V1 of one of the semiconductor patterns SP may be disposed between the second portions WL1b of the first word line WL1. The second vertical portion V2 of another one of the semiconductor patterns SP may be disposed between the second portions WL2b of the second word line WL2.

The first and second word lines WL1 and WL2 may include a conductive material. For example, the first and second word lines WL1 and WL2 may include at least one of a doped semiconductor material (e.g., doped silicon, doped germanium, etc.), a conductive metal nitride (e.g., titanium nitride, tantalum nitride, etc.), a metal (e.g., tungsten, titanium, tantalum, etc.), and a metal-semiconductor compound (e.g., tungsten silicide, cobalt silicide, titanium silicide, etc.).

The first word line WL1 may include an inner wall IS1 and an outer wall OS1 facing each other in the first direction D1. For example, the inner wall IS1 of the first word line WL1 may be a sidewall in which the second portions WL1b of the first word line WL1 are not disposed. When viewed in a plan view, the inner wall IS1 of the first word line WL1 may extend in a straight line in the second direction D2. The outer sidewall OS1 of the first word line WL1 may be another sidewall where the second portions WL1b of the first word line WL1 are disposed. When viewed in a plan view, the outer wall OS1 of the first word line WL1 may extend in a winding shape in the second direction D2. Specifically, the outer sidewall OS1 of the first word line WL1 may include the first to third sidewalls S11, S12, and S13 of the second portions WL1b of the first word line WL1. In addition, the outer wall OS1 of the first word line WL1 may include a sidewall of the first portion WL1a of the first word line WL1 connecting the second portion WL1b in the second direction D2, between the second portions WL1b neighboring each other in the second direction D2.

The second word line WL2 may include an inner wall IS2 and an outer wall OS2 facing each other in the first direction D1. For example, the inner wall IS2 of the second word line WL2 may be a sidewall in which the second portions WL2b of the second word line WL2 are not disposed. When viewed in a plan view, the inner wall IS2 of the second word line WL2 may extend in a straight line in the second direction D2. The outer sidewall OS2 of the second word line WL2 may be another sidewall where the second portions WL2b of the second word line WL2 are disposed. When viewed in a plan view, the outer wall OS2 of the second word line WL2 may extend in a winding shape in the second direction D2. Specifically, the outer sidewall OS2 of the second word line WL2 may include the first to third sidewalls S21, S22, and S23 of the second portions WL2b of the second word line WL2. In addition, the outer wall OS2 of the second word line WL2 may include a sidewall of the first portion WL2a of the second word line WL2 connecting the second portions WL2b in the second direction D2, between the second portions WL2b neighboring each other in the second direction D2.

The inner wall IS1 of the first word line WL1 and the inner wall IS2 of the second word line WL2 may face each other. The semiconductor pattern SP may not exist between the inner wall IS1 of the first word line WL1 and the inner wall IS2 of the second word line WL2.

A first gate insulating layer GI1 may be interposed between the outer wall OS1 of the first word line WL1 and the first vertical portions V1 of the corresponding semiconductor patterns SP. The first gate insulating layer GI1 may be in contact with the outer wall OS1 of the first word line WL1 and the first vertical portions V1 of the semiconductor patterns SP. The first vertical portions V1 of the semiconductor patterns SP may be spaced apart from the first word line WL1 with the first gate insulating layer GI1 interposed therebetween. When viewed in a plan view, the first gate insulating layer GI1 may extend in a winding shape in the first direction D1. When viewed in a plan view, the first gate insulating layer GI1 may have a shape that conformally surrounds the outer wall OS1 of the first word line WL1. Specifically, the first gate insulating layer GI1 may include an inner portion GI1a in contact with the outer walls SPo of the first vertical portions V1, an outer portion GI1b in contact with the third sidewalls S13 of the second portions WL1b of the first word line WL1, and a connection portion GI1c connecting the inner portion GI1a and the outer portion GI1b. The first vertical portions V1 of the semiconductor patterns SP may be spaced apart from the first word line WL1 by the inner portion GI1a and the connection portion GI1c of the first gate insulating layer GI1. A lower surface of the first gate insulating layer GI1 may be in contact with an upper surface of the support insulating layer 10.

A second gate insulating layer GI2 may be interposed between the outer wall OS2 of the second word line WL2 and the second vertical portions V2 of the corresponding semiconductor patterns SP. The second gate insulating layer GI2 may be in contact with the outer wall OS2 of the second word line WL2 and the second vertical portions V2 of the semiconductor patterns SP. The second vertical portions V2 of the semiconductor patterns SP may be spaced apart from the second word line WL2 with the second gate insulating layer GI2 therebetween. When viewed in a plan view, the second gate insulating layer GI2 may extend in a winding shape in the first direction D1. When viewed in a plan view, the second gate insulating layer GI2 may have a shape that conformally surrounds the outer wall OS2 of the second word line WL2. Specifically, the second gate insulating layer GI2 may include an inner portion GI2a in contact with the outer walls SPo of the second vertical portion V2, an outer portion GI2b in contact with the third sidewalls S23 of the second portions WL2b of the second word line WL2, and a connection portion GI2c connecting the inner portion GI2a and the outer portion GI2b. Each of the second vertical portions V2 of the semiconductor patterns SP may be spaced apart from the second word line WL2 by the inner portion GI2a and the connection portion GI2c of the second gate insulating layer GI2. The lower surface of the second gate insulating layer GI2 may be in contact with the upper surface of the support insulating layer 10.

A third gate insulating layer GI3 may be disposed on the inner wall IS1 of the first word line WL1 and the inner wall IS2 of the second word line WL2. The third gate insulating layer GI3 may extend in the second direction D2. The third gate insulating layer GI3 may include vertical portions GI3v and horizontal portions GI3h. The vertical portions GI3v of the third gate insulating layer GI3 may face each other in the first direction D1. The vertical portions GI3v of the third gate insulating layer GI3 may be in contact with the inner wall IS1 of the first word line WL1 and the inner wall IS2 of the second word line WL2, respectively. The horizontal portion GI3h of the third gate insulating layer GI3 may be adjacent to a lower portion of the vertical portions GI3v and connect the vertical portions GI3v. The horizontal portion GI3h of the third gate insulating layer GI3 may be in contact with the upper surface of the support insulating layer 10. The first and second word lines WL1 and WL2 and the third gate insulating layer GI3 may be provided between the first and second gate insulating layers GI1 and GI2.

The first to third gate insulating layers GI1, GI2, and GI3 may include at least one of silicon oxide, silicon oxynitride, and a high-k material having a higher dielectric constant than silicon oxide. The high-k material may include metal oxide or metal oxynitride. For example, the high-k material usable as the first to third gate insulating layers GI1, GI2, and GI3 may include at least one of HfO2, HfSiO, HfSiON, HfTaO, HfTiO, HfZrO, ZrO₂, and Al₂O₃, but is not limited thereto.

The gate capping layer GP may be provided on the first and second word lines WL1 and WL2 and the first to third gate insulating layers GI1, GI2, and GI3. A lower surface of the gate capping layer GP may be in contact with upper surfaces of the first and second word lines WL1 and WL2 and the first to third gate insulating layers GI1, GI2, and GI3. The upper surfaces of the first and second word lines WL1 and WL2 and the upper surfaces of the first to third gate insulating layers GI1, GI2, and GI3 may be coplanar. Heights of the upper surfaces of the first and second word lines WL1 and WL2 and the first to third gate insulating layers GI1, GI2, and GI3 may be lower than heights of upper surfaces of the vertical portions VC of the semiconductor pattern SP. In this specification, the height may be a height measured in the third direction D3 from the upper surface 100a of the substrate 100.

A sidewall of the gate capping layer GP may be coplanar with a sidewall of the first gate insulating layer GI1 or a sidewall of the second gate insulating layer GI2. The sidewall of the gate capping layer GP may be in contact with the vertical portions VC of the semiconductor pattern SP. The gate capping layer GP may include an insulating material. As an example, the gate capping layer GP may include silicon nitride.

A cell insulating layer 200 may be disposed in the gate structure GST. The cell insulating layer 200 may be disposed between the first and second word lines WL1 and WL2. The cell insulating layer 200 may be surrounded by the third gate insulating layer GI3 and the gate capping layer GP of the gate structure GST. A lower surface of the cell insulating layer 200 may be in contact with an upper surface of the connection portion GI3h of the third gate insulating layer GI3. An upper surface of the cell insulating layer 200 may be in contact with a lower surface of the gate capping layer GP.

The cell insulating layer 200 may include a low-k material. The low dielectric material may include an insulating material with a lower dielectric constant than the material included in the first to third gate insulating layers GI1, GI2, and GI3, the support insulating layer 10, and the gate capping layer GP. As an example, the cell insulating layer 200 may include an insulating material with a dielectric constant (k) of about 2.5 or less than 2.0, for example, porous SiOC.

An insulating pattern 210 may be interposed between gate structures GST that are adjacent to each other in the first direction D1. The insulating pattern 210 may be disposed on the semiconductor patterns SP respectively disposed on the bit lines BL and may be spaced apart from each other in the second direction D2. The insulating pattern 210 may be in contact with the upper surface of the horizontal portion HC of the semiconductor pattern SP and the inner walls SPi of the vertical portions V1. The insulating pattern 210 may extend in the second direction D2 and may cross the bit line BL. The insulating patterns 210 may be spaced apart from each other in the first direction D1. The insulating pattern 210 may include an insulating material. As an example, the insulating pattern 210 may include silicon oxide, silicon nitride, and/or silicon oxynitride.

Landing pads LP may be provided on the semiconductor patterns SP. The landing pad LP may be connected to the upper surface of the vertical portions VC of the semiconductor pattern SP. The landing pad LP may be spaced apart from the first to third gate insulating layers GI1, GI2, and GI3. The landing pad LP may include at least one of a conductive material. For example, the landing pad LP may be formed of a doped semiconductor material (e.g., doped silicon, doped germanium, etc.), a conductive metal nitride (e.g., titanium nitride, tantalum nitride, etc.), a metal (e.g., tungsten, titanium, tantalum, etc.), and a metal-semiconductor compound (e.g., tungsten silicide, cobalt silicide, titanium silicide, etc.).

A separation insulating pattern INP may be provided between the landing pads LP. The separation insulating pattern INP may be provided on the gate capping layer GP. The separation insulating pattern INP may separate the landing pads LP. The separation insulating pattern INP may include an insulating material. In some implementations, the separation insulating pattern INP may be a multilayer including a plurality of insulating layers.

Data storage patterns DSP may be respectively connected to the landing pads LP. The data storage patterns DSP may be electrically connected to the semiconductor pattern SP through landing pads LP.

In some implementations, the data storage pattern DSP may be a capacitor. In this case, the data storage pattern DSP may include a lower electrode, an upper electrode, and a capacitor dielectric layer interposed therebetween. In this case, the lower electrode may be in contact with the landing pad LP, and the lower electrode may have various shapes, such as circular, oval, rectangular, square, diamond, or hexagon, when viewed in a plan view.

Additionally or alternatively, the data storage patterns DSP may be variable resistance patterns that may be switched between two resistance states by electrical pulses applied to the memory element. For example, the data storage patterns DSP may include a phase-change material, a perovskite compound, a transition metal oxide, a magnetic material, a ferromagnetic material, or an antiferromagnetic material whose crystal state changes depending on the amount of current.

An oxide semiconductor with a vertical channel structure may have a transistor form in which the overlapping area between the semiconductor pattern SP and the word line is relatively small. Accordingly, the area of the channel that may be controlled by the gate may be relatively small, and as a result, there is a problem that electrical characteristics of the semiconductor device are deteriorated.

Advantageously, the word line may surround the vertical portions VC of the semiconductor pattern SP on three sides. The vertical portions VC of the semiconductor pattern SP may be interposed between the second portions WL1b and WL2b of the first and second word lines WL1 and WL2. That is, the semiconductor pattern SP may have a structure where the word line WL1b and WL2b surrounds the sides of the channel. Accordingly, the overlapping area between the semiconductor pattern SP and the word line may increase, and as a result, the area of the channel capable of being controlled by the gate may increase. Accordingly, a semiconductor device with improved electrical characteristics may be provided.

Additionally, the cell insulating layer 200 including the low-k material may be disposed between the first and second word lines WL1 and WL2. Accordingly, parasitic capacitance between the first and second word lines WL1 and WL2 may be reduced, and characteristics of the semiconductor device may be improved. In addition, electrical interference may be reduced, thereby improving integration of wiring.

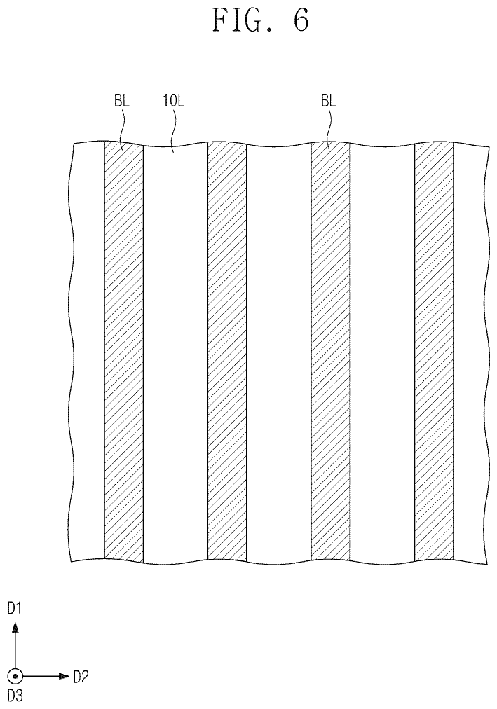

FIGS. 6 to 21C are views for explaining an example of a method of manufacturing a semiconductor device. For simplicity of explanation, the repeated description of elements as described above is omitted.

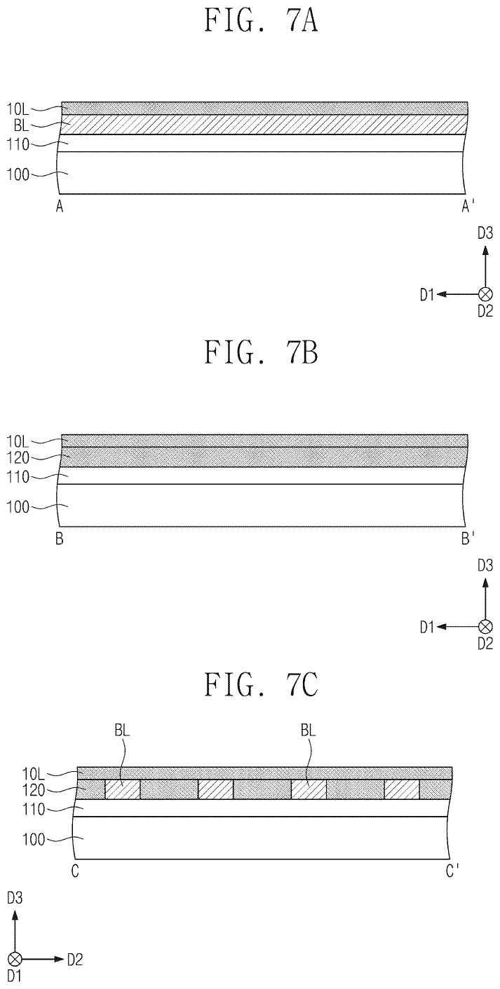

Referring to FIGS. 6 and 7A to 7C, a first lower insulating layer 110 may be formed on a substrate 100. A second lower insulating layer 120 may be formed on the first lower insulating layer 110. Bit lines BL may be formed in the second lower insulating layer 120. Forming the bit lines BL may include, for example, forming a mask pattern (not shown) on the second lower insulating layer 120, patterning the second lower insulating layer 120 to using the mask pattern as an etch mask to form a trench (not shown), and filling the trench to the bit lines BL.

A preliminary support insulating layer 10L may be formed on the bit lines BL and the second lower insulating layer 120. Forming the preliminary support insulating layer 10L may be formed using at least one of physical vapor deposition (PVD), thermal chemical vapor deposition (thermal CVD), low pressure chemical vapor deposition (LP-CVD), plasma enhanced chemical vapor deposition (PE-CVD), and atomic layer deposition (ALD) techniques.

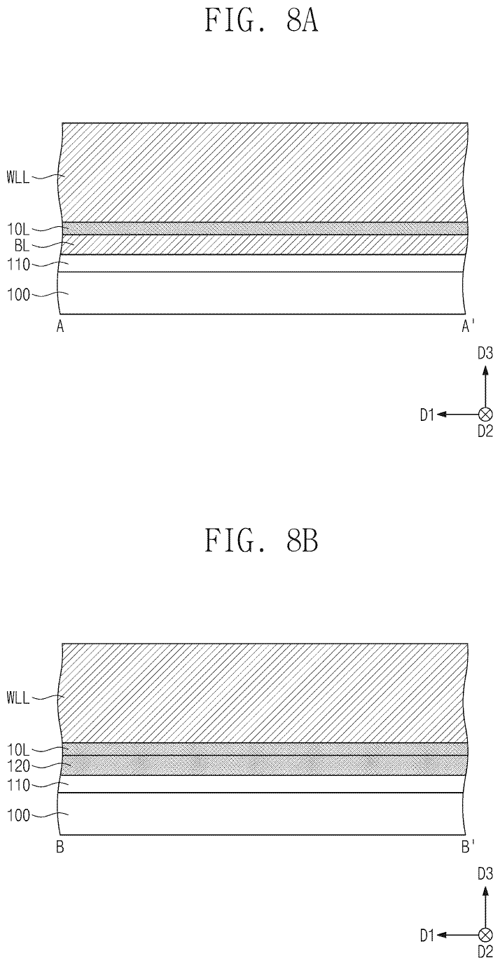

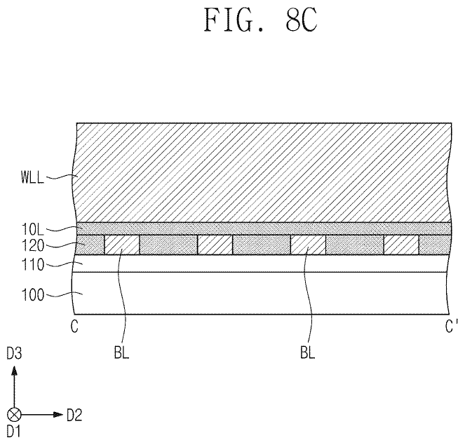

Referring to FIGS. 8A to 8C, a word line layer WLL may be formed on the preliminary support insulating layer 10L. The word line layer WLL may include a conductive material.

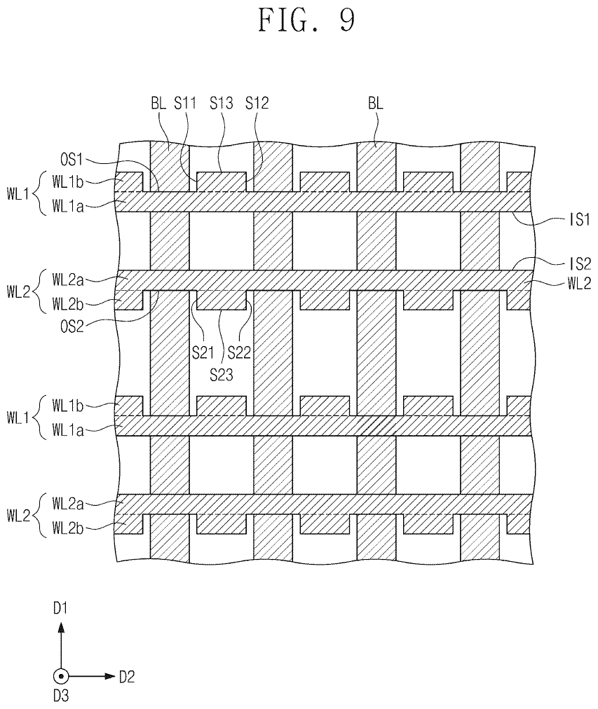

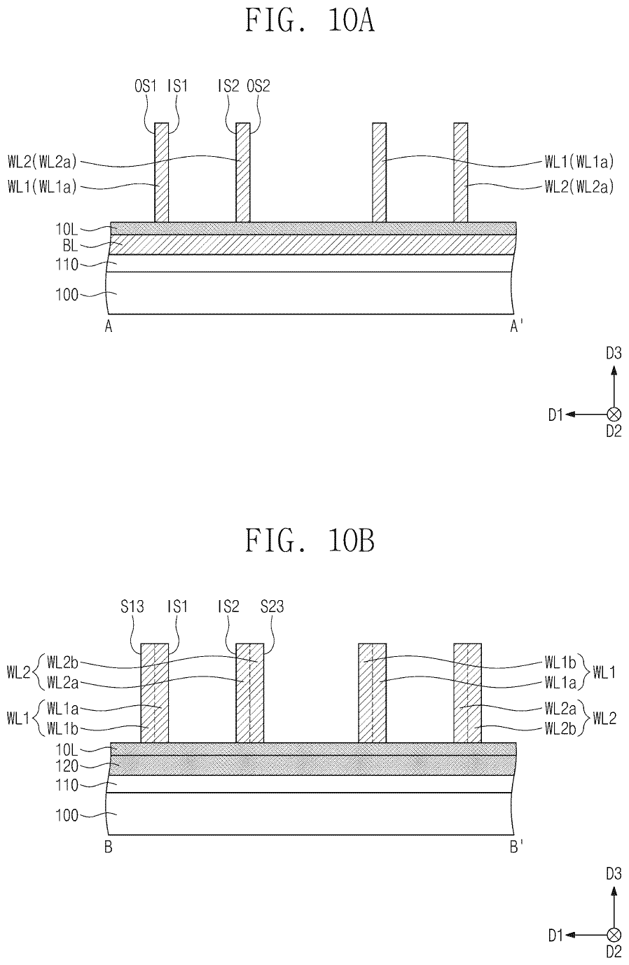

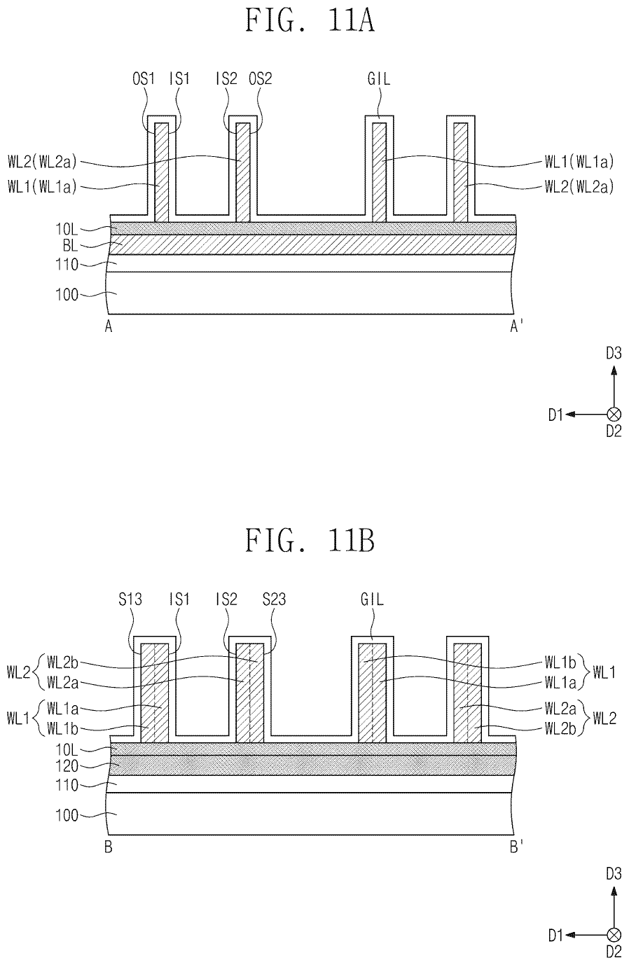

Referring to FIGS. 9, 10A, and 10B, first word lines WL1 and second word lines WL2 may be formed on the preliminary support insulating layer 10L. For example, forming the first word lines WL1 and the second word lines WL2 may include forming a mask pattern (not shown) on the word line layer WLL, patterning the word line layer WLL using the mask pattern as an etch mask, and removing the mask pattern.

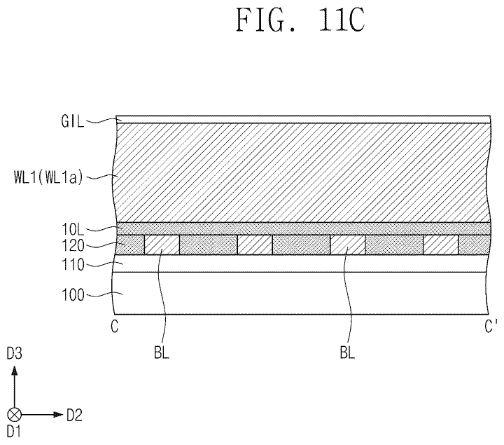

Referring to FIGS. 11A to 11C, a preliminary gate insulating layer GIL may be formed. The preliminary gate insulating layer GIL may be conformally formed on the preliminary support insulating layer 10L, the first word lines WL1, and the second word lines WL2. Forming the preliminary gate insulating layer GIL may be formed using a layer deposition technology with excellent step coverage, such as physical vapor deposition (PVD), thermal chemical vapor deposition (thermal CVD), low pressure chemical vapor deposition (LP-CVD), plasma enhanced chemical vapor deposition (PE-CVD), and atomic layer deposition (ALD).

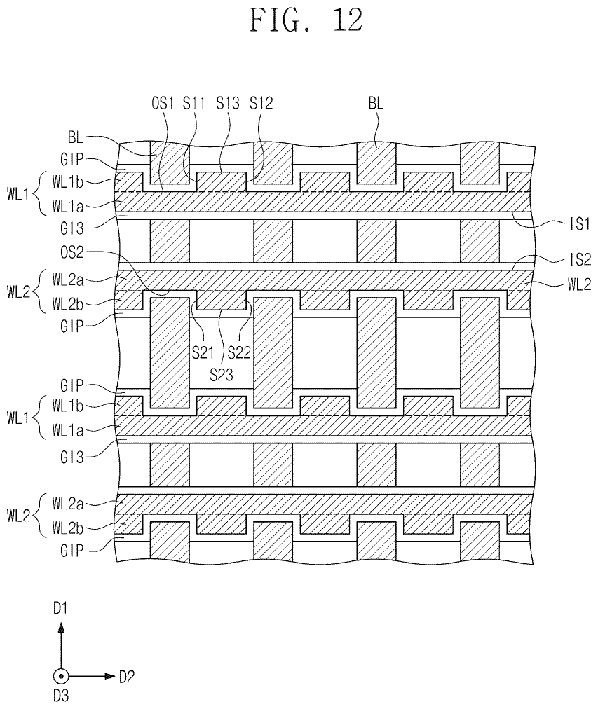

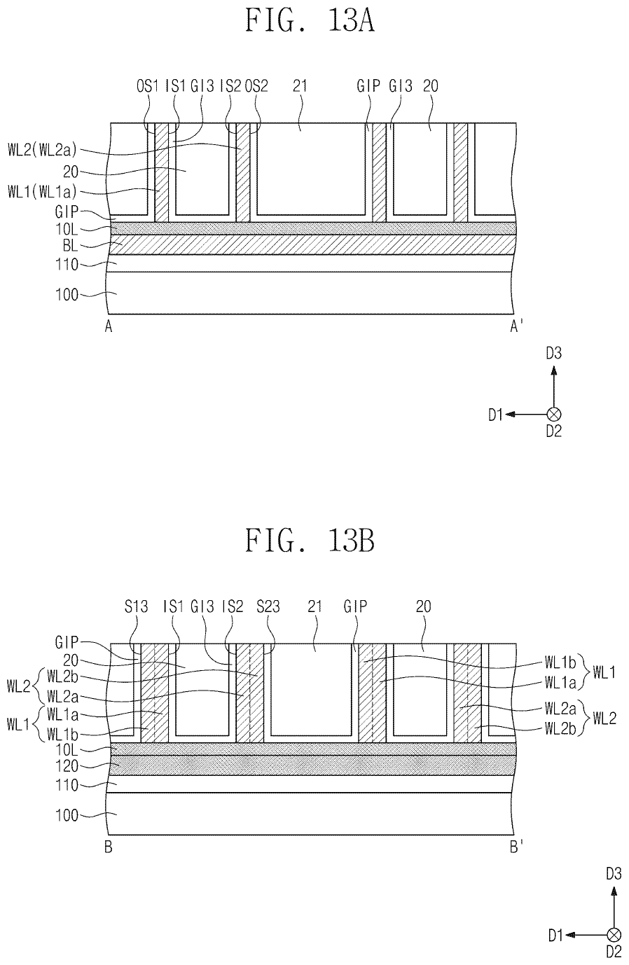

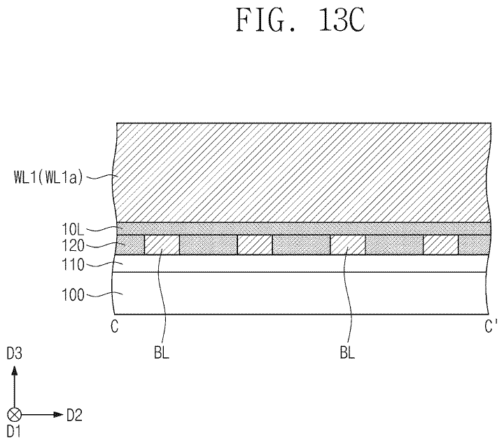

Referring to FIGS. 12 and 13A to 13C, first sacrificial layers 20, second sacrificial layers 21, the preliminary gate insulating patterns GIP, and third gate insulating layers GI3 may be formed. The first sacrificial layers 20 may be formed on the third gate insulating layers GI3. The second sacrificial layers 21 may be formed on the preliminary gate insulating patterns GIP. The first sacrificial layers 20 and second sacrificial layers 21 may be alternately arranged in the first direction D1. For example, forming the first sacrificial layers 20, second sacrificial layers 21, preliminary gate insulating patterns GIP, and third gate insulating layers GI3 may include, for example, forming a preliminary sacrificial layer (not shown) on the preliminary gate insulating layer GIL, and planarizing an upper portion of the preliminary sacrificial layer and an upper portion of the preliminary gate insulating layer GIL until an upper surfaces of the first and second word lines WL1 and WL2 are exposed. The planarizing may be performed, for example, through a chemical mechanical polishing (CMP) process or an etch back process.

The upper portion of the preliminary gate insulating layer GIL may be removed to separate the preliminary gate insulating layer GIL into preliminary gate insulating patterns GIP and third gate insulating layers GI3. The upper portion of the preliminary sacrificial layer may be removed to separate the preliminary sacrificial layer into first sacrificial layers 20 and second sacrificial layers 21. The first and second sacrificial layers 20 and 21 may include an insulating material. As an example, the first and second sacrificial layers 20 and 21 may include a low-k material.

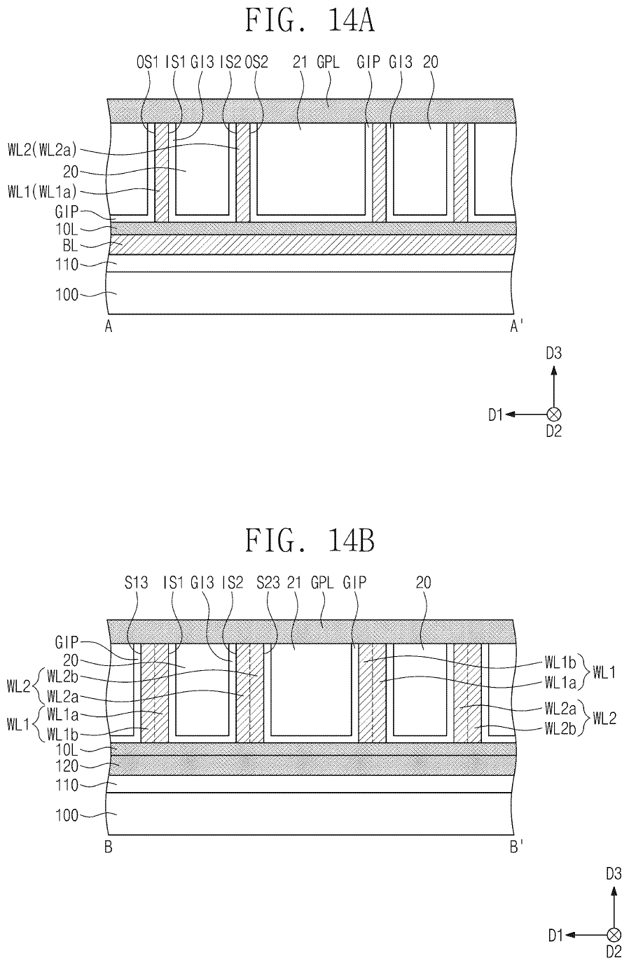

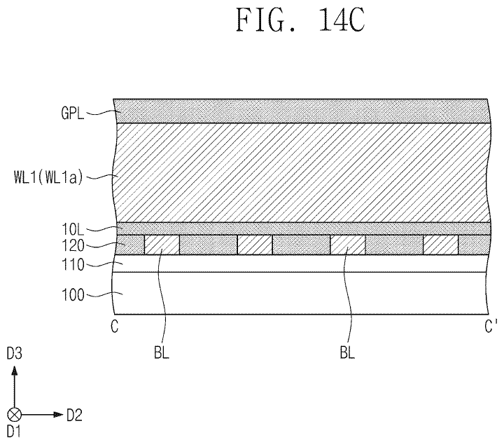

Referring to FIGS. 14A to 14C, a preliminary gate capping layer GPL may be formed. The preliminary gate capping layer GPL may cover the first and second sacrificial layers 20 and 21, the third gate insulating layers GI, the preliminary gate insulating patterns GIP, and the first and second word lines WL1 and WL2.

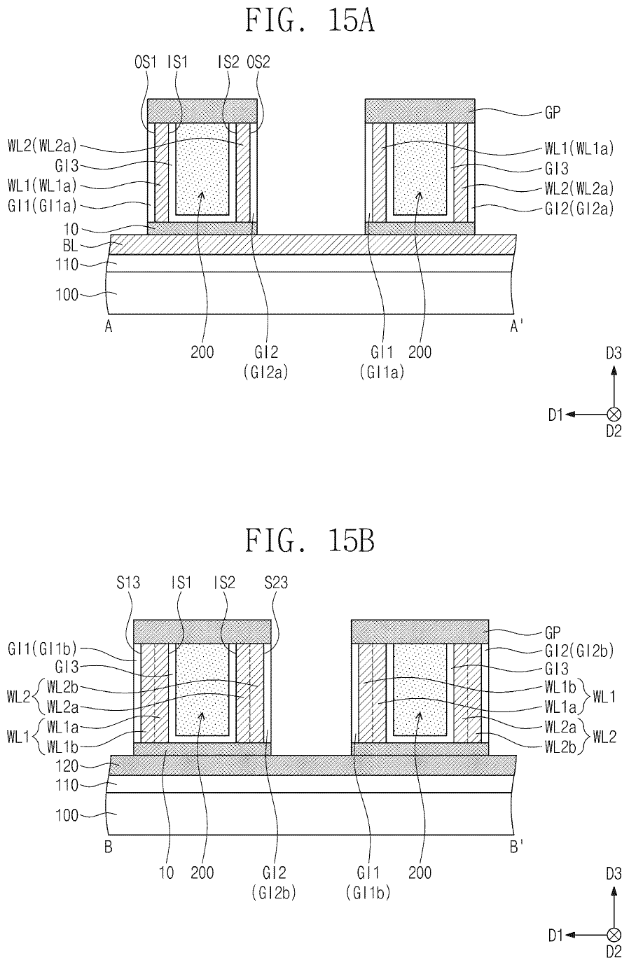

Referring to FIGS. 15A and 15B, gate capping layers GP, first gate insulating layers GI1, second gate insulating layers GI2, and support insulating layers 10 may be formed. For example, forming the gate capping layers GP, first gate insulating layers GI1, second gate insulating layers GI2, and support insulating layers 10 may include, for example, forming a mask pattern (not shown) on the preliminary gate capping layer GPL, sequentially etching the preliminary gate capping layer GPL, preliminary gate insulating patterns GIP, and preliminary support insulating layer 10L using the mask pattern as an etch mask, and removing the mask pattern.

The preliminary gate capping layer GPL may be patterned and separated into gate capping layers GP. The preliminary gate insulating pattern GIP may be patterned and separated into a first gate insulating layer GI1 and a second gate insulating layer GI2. The preliminary support insulating layer 10L may be patterned and separated into support insulating layers 10. The preliminary support insulating layer 10L may be patterned to expose upper surfaces of the bit line BL and the second lower insulating layer 120.

Before or simultaneously with patterning the preliminary gate insulating pattern GIP, the second sacrificial layer 21 on the preliminary gate insulating pattern GIP may be removed. The first sacrificial layer 20 may remain on the third gate insulating layer GI3. The first sacrificial layer 20 remaining on the third gate insulating layer GI3 may be referred to as a cell insulating layer 200.

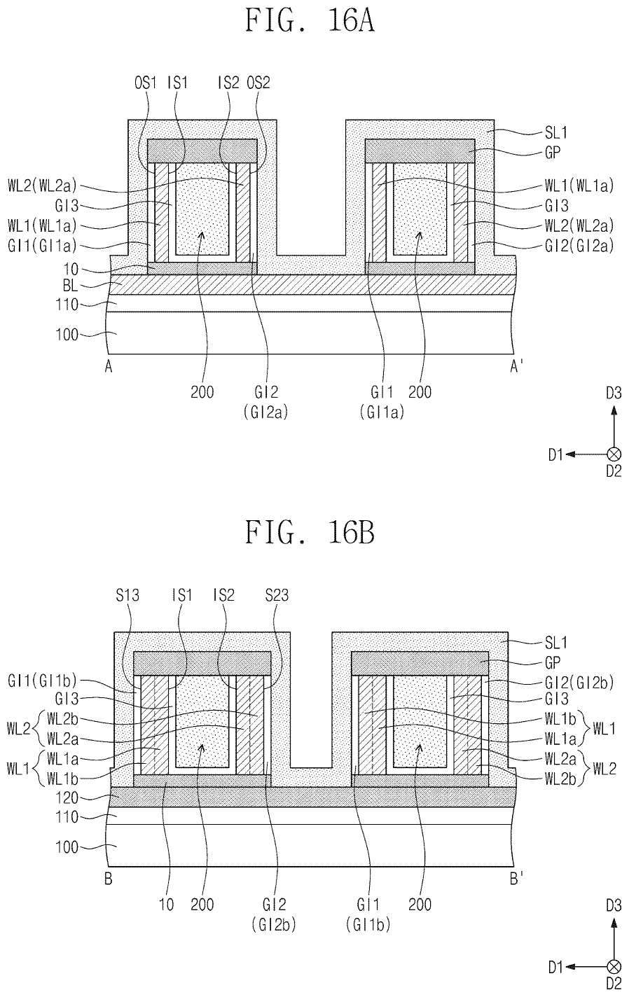

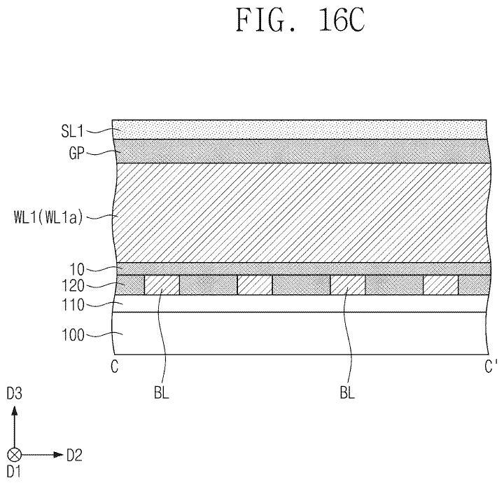

Referring to FIGS. 16A to 16C, a first semiconductor layer SL1 may be formed. The first semiconductor layer SL1 may be conformally formed on the second lower insulating layer 120, bit lines BL, first to third gate insulating layers GI1, GI2, and GI3, support insulating layers 10, and gate capping layers GP. For example, forming the first semiconductor layer SL1 may be formed using a layer deposition technology with excellent step coverage, such as physical vapor deposition (PVD), thermal chemical vapor deposition (thermal CVD), low pressure chemical vapor deposition (LP-CVD), plasma enhanced chemical vapor deposition (PE-CVD), and atomic layer deposition (ALD).

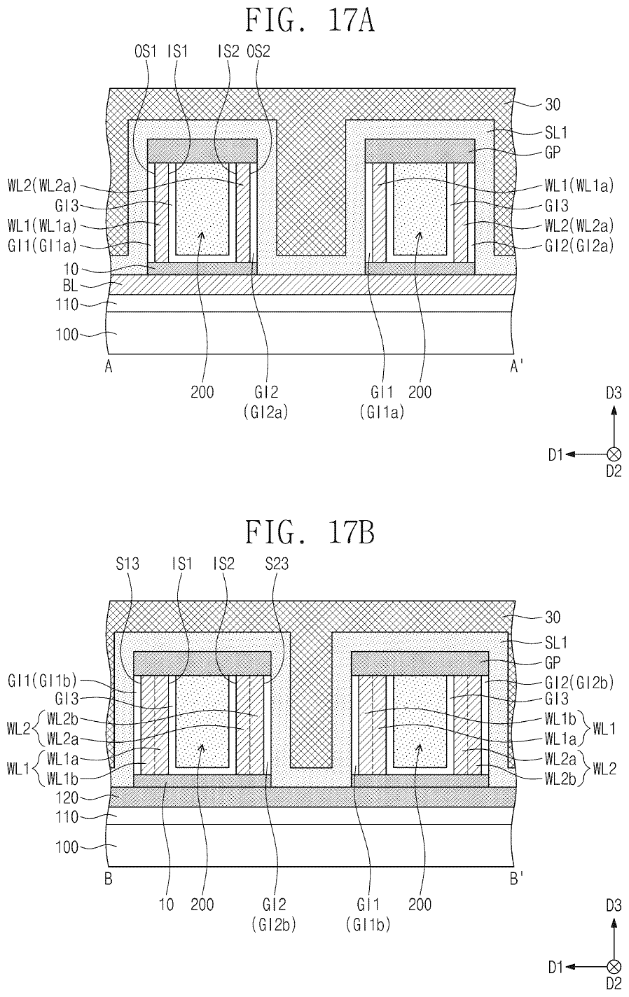

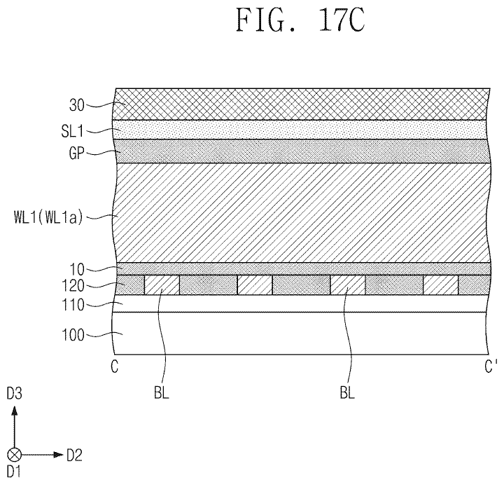

Referring to FIGS. 17A to 17C, a third sacrificial layer 30 may be formed on the first semiconductor layer SL1. The third sacrificial layer 23 may include an insulating material. As an example, the third sacrificial layer 23 may include a spin on hardmask (SOH).

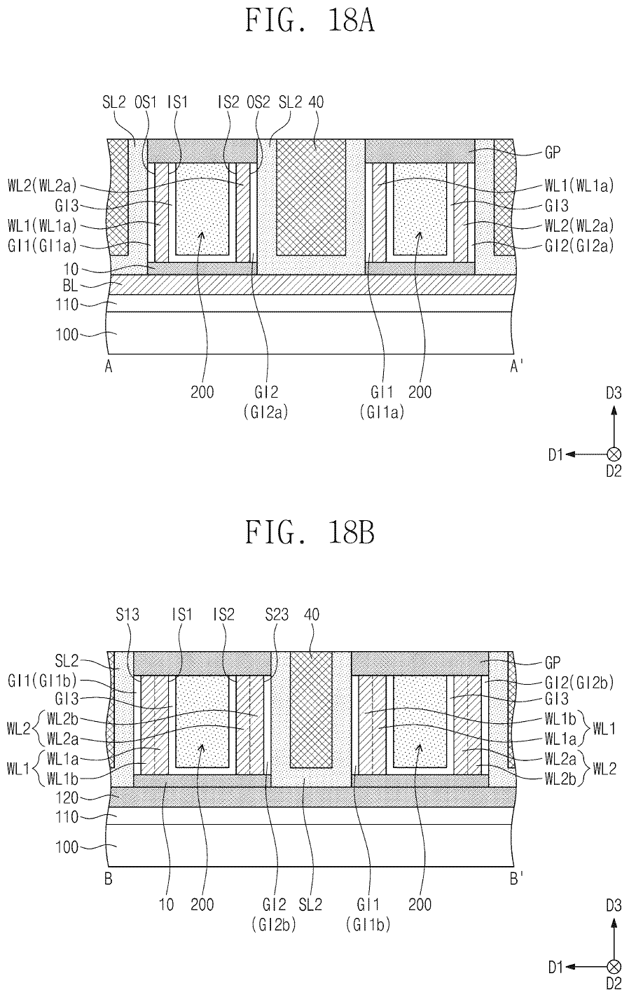

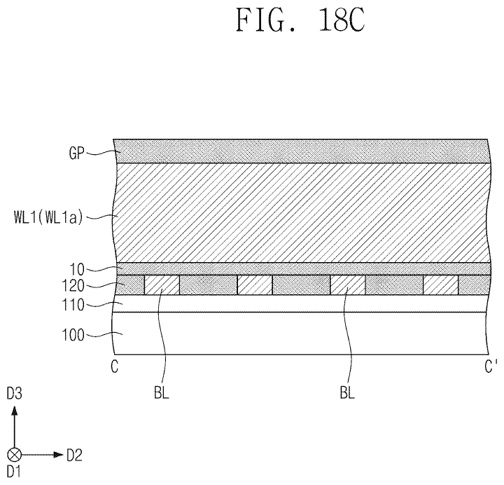

Referring to FIGS. 18A to 18C, fourth sacrificial layers 40 and second semiconductor layers SL2 may be formed. For example, forming the fourth sacrificial layers 40 and the second semiconductor layers SL2 may include planarizing an upper portion of the third sacrificial layer 30 and an upper portion of the first semiconductor layer SL1 until an upper surface of the gate capping layer GP is exposed. Planarizing may be performed, for example, through a chemical mechanical polishing (CMP) process or an etch back process.

The upper portion of the third sacrificial layer 30 may be removed and separated into fourth sacrificial layers 40. The fourth sacrificial layers 40 may be spaced apart from each other in the first direction D1 and may extend in the second direction D2. The upper portion of the first semiconductor layer SL1 may be removed and separated into second semiconductor layers SL2.

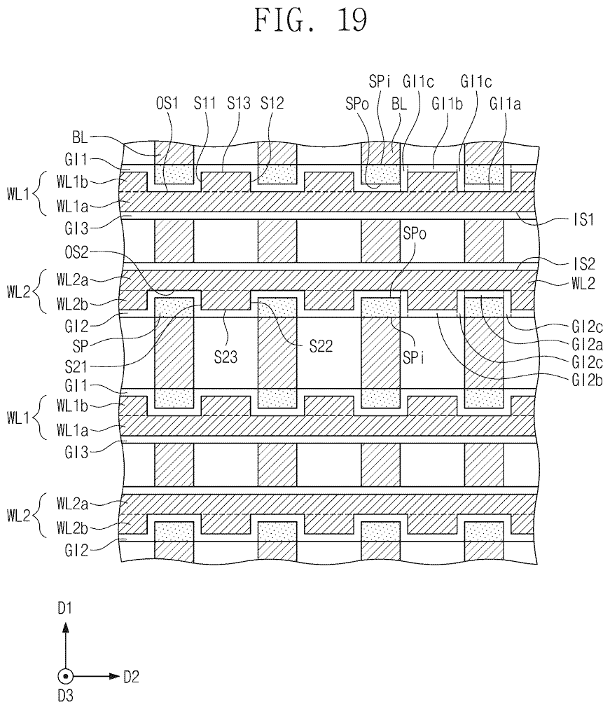

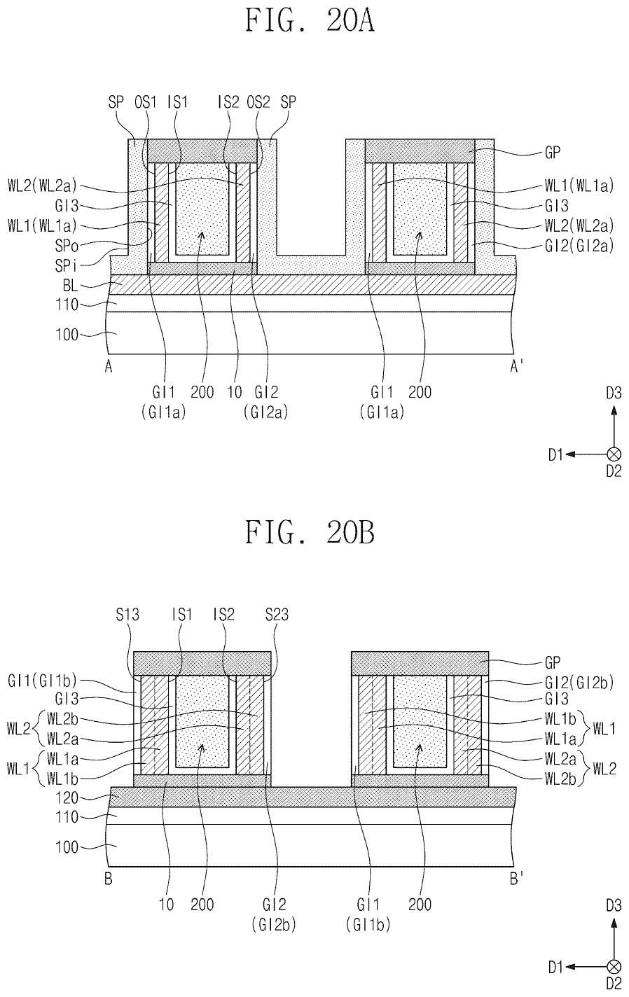

Referring to FIGS. 19, 20A, and 20B, semiconductor patterns SP may be formed. For example, forming the semiconductor patterns SP may include forming a mask pattern (not shown) that vertically overlaps the bit lines BL, sequentially etching the exposed fourth sacrificial layer 40 and the second semiconductor layer SL2 using the mask pattern as an etch mask, removing the mask pattern, and removing the remainder of the fourth sacrificial layer 40.

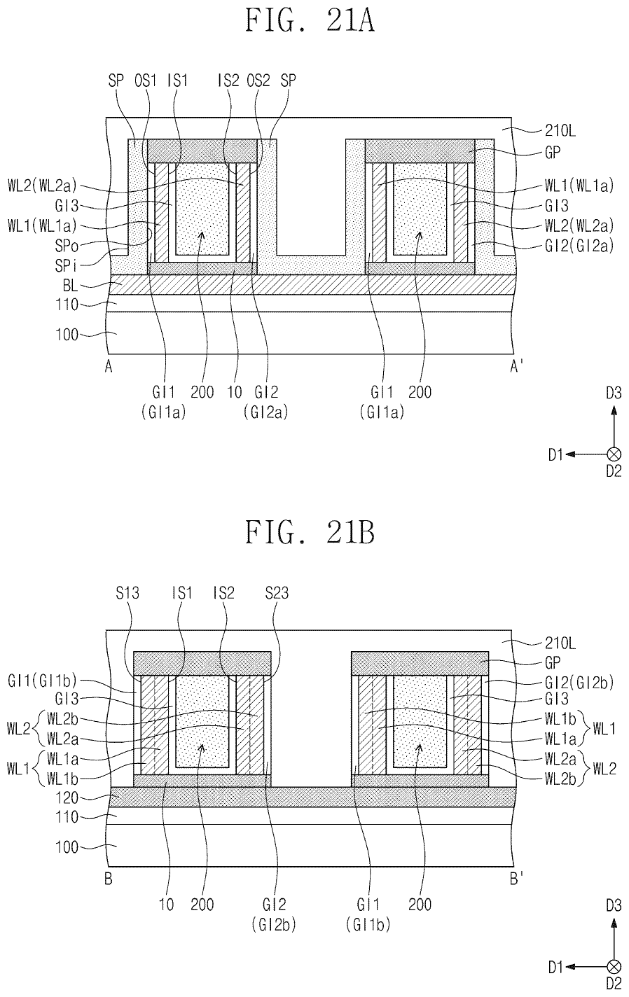

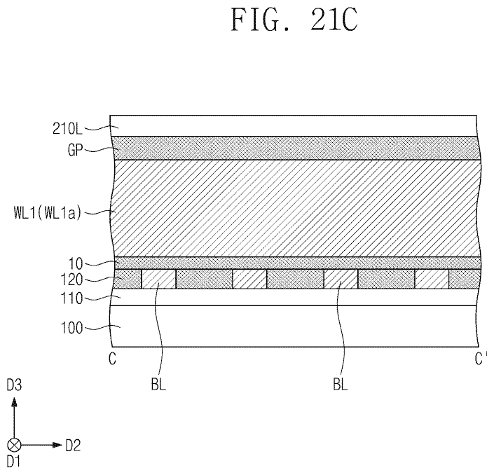

Referring to FIGS. 21A to 21C, an insulating pattern layer 210L may be formed. The insulating pattern layer 210L may cover the semiconductor patterns SP, gate capping layers GP, and the second lower insulating layer 120.

Referring again to FIGS. 4 and 5A to 5C, an upper portion of the insulating pattern layer 210L may be removed to form an insulating pattern 210. Removing the upper portion of the insulating pattern layer 210L may include, for example, planarizing the insulating pattern layer 210L until an upper surface of the gate capping layer GP is exposed.

Landing pads LP and separation insulating patterns INP may be formed. The landing pad LP may fill an empty space formed by removing the upper portion of the semiconductor pattern SP. Data storage patterns DSP connected to the landing pads LP may be formed.

In some implementations, with the first to third gate insulating layers GI1, GI2, and GI3 protected by the insulating patterns 210 and the semiconductor patterns SP, damage to the first to third gate insulating layers GI1, GI2, and GI3 may be prevented or restricted during forming the landing pad LP.

In some implementations, after forming the first and second word lines WL1 and WL2, the first to third gate insulating layers GI1, GI2, and GI3 may be formed, thereby preventing or restricting damage to the gate insulating layers GI1, GI2, and GI3.

In some implementations, as the first to third gate insulating layers GI1, GI2, and GI3 are formed through a single deposition process, the number of interfaces of the first to third gate insulating layers GI1, GI2, and GI3 may be relatively small, and reliability of the first to third gate insulating layers GI1, GI2, and GI3 may be improved.

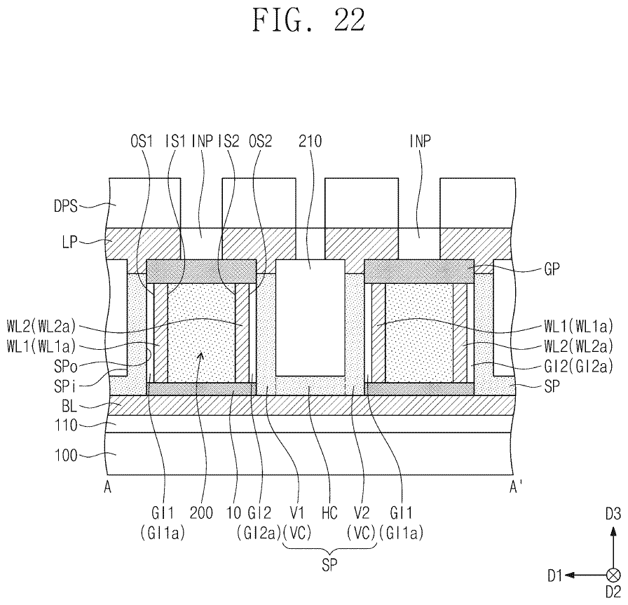

FIGS. 22 to 28 are cross-sectional views of semiconductor devices. For simplicity of explanation, content that overlaps with the above is omitted.

Referring to FIG. 22, in some implementations, a cell insulating layer 200 may be disposed between a first word line WL1 and a second word line WL2 of the semiconductor device. A lower surface of the cell insulating layer 200 may be in contact with an upper surface of a support insulating layer 10. An upper surface of the cell insulating layer 200 may be in contact with a lower surface of a gate capping layer GP. In this case, a third gate insulating layer GI3 described with reference to FIGS. 4 and 5A to 5C may be omitted. Accordingly, the cell insulating layer 200 may be in direct contact with an inner wall IS1 of a first word line WL1 and an inner wall IS2 of a second word line WL2.

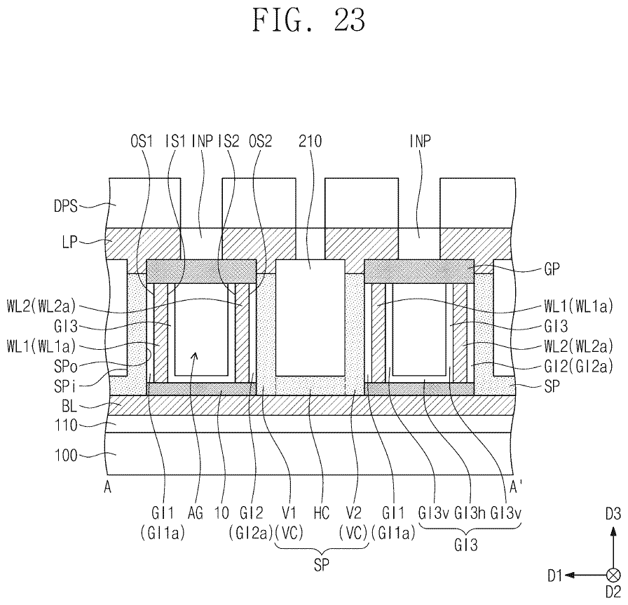

Referring to FIG. 23, in some implementations, an air gap AG may be provided on a third gate insulating layer GI3. The air gap AG may be interposed between vertical portions GI3v of the third gate insulating layer GI3. For example, boundaries of the vertical portions GI3v of the third gate insulating layer GI3 define the air gap. The air gap AG may expose a horizontal portion GI3h of the third gate insulating layer GI3. For example, the air gap AG may be an empty space filled with air.

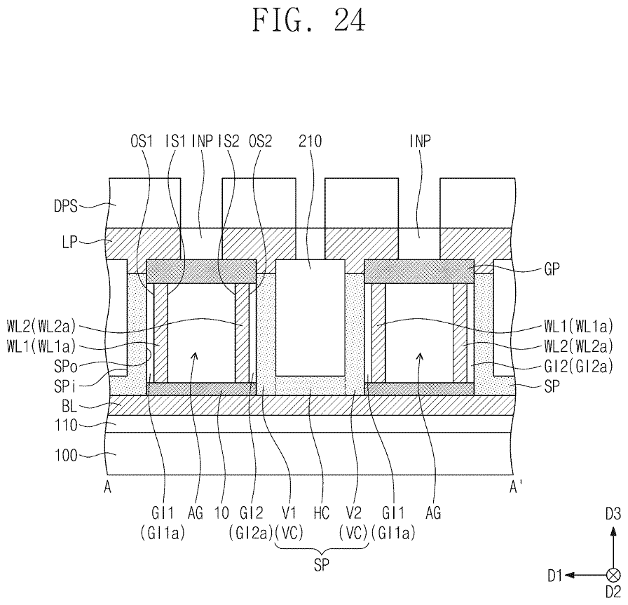

Referring to FIG. 24, in some implementations, the third gate insulating layer GI3 described with reference to FIGS. 4 and 5A to 5C may be omitted, and the air gap AG may be provided between the first word line WL1 and the second word line WL2. The air gap AG may expose an inner wall IS1 of the first word line WL1 and the inner wall IS2 of the second word line WL2. The air gap AG may expose an upper surface of the support insulating layer 10. The air gap AG may expose a lower surface of the gate capping layer GP.

In FIGS. 23 and 24, the air gap AG is provided between the first and second word lines WL1 and WL2 instead of the cell insulating layer 200. The air gap AG may have a lower dielectric constant than the cell insulating layer 200. Accordingly, parasitic capacitance between the first and second word lines WL1 and WL2 may be reduced, and characteristics of the semiconductor device may be improved. In addition, electrical interference may be reduced, thereby increasing integration of wiring.

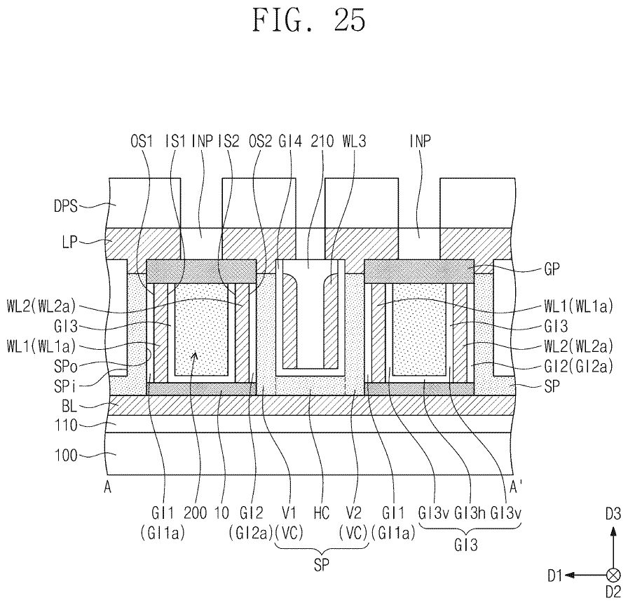

Referring to FIG. 25, in some implementations, a fourth gate insulating layer GI4 on the semiconductor pattern SP and third word lines WL3 on the fourth gate insulating layer GI4 may be provided. The third word lines WL3 may be spaced apart from each other in the first direction D1 with the insulating pattern 210 interposed therebetween. The first vertical portion V1 of the semiconductor pattern SP may be disposed between the first word line WL1 and the third word line WL3. The second vertical portion V2 of the semiconductor pattern SP may be disposed between the second word line WL2 and the third word line WL3. The fourth gate insulating layer GI4 may be in contact with the landing pad LP.

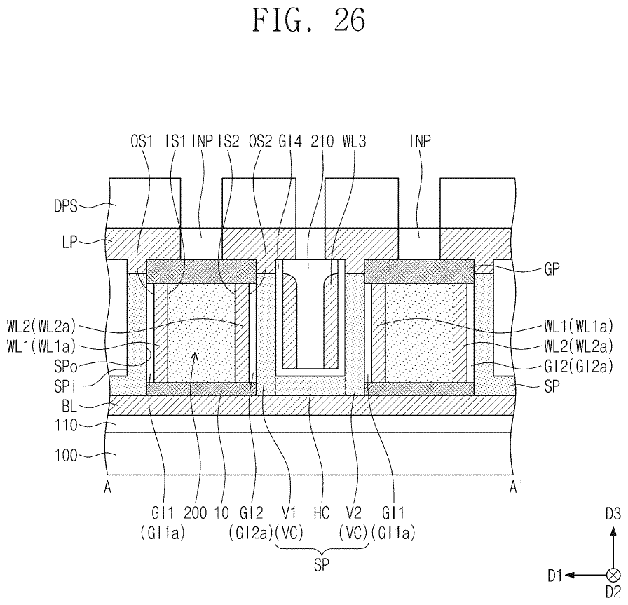

Referring to FIG. 26, in some implementations, a fourth gate insulating layer GI4 on the semiconductor pattern SP and third word lines WL3 on the fourth gate insulating layer GI4 may be provided. The third word lines WL3 may be spaced apart from each other in the first direction D1 with the insulating pattern 210 interposed therebetween. The first vertical portion V1 of the semiconductor pattern SP may be disposed between the first word line WL1 and the third word line WL3. The second vertical portion V2 of the semiconductor pattern SP may be disposed between the second word line WL2 and the third word line WL3. The fourth gate insulating layer GI4 may be in contact with the landing pad LP. A cell insulating layer 200 may be disposed between the first and second word lines WL1 and WL2. A lower surface of the cell insulating layer 200 may be in contact with an upper surface of the support insulating layer 10. An upper surface of the cell insulating layer 200 may be in contact with a lower surface of the gate capping layer GP. In this case, the third gate insulating layer GI3 described with reference to FIGS. 4 and 5A to 5C may be omitted. Accordingly, the cell insulating layer 200 may be in direct contact with an inner wall IS1 of the first word line WL1 and the inner wall IS2 of the second word line WL2.

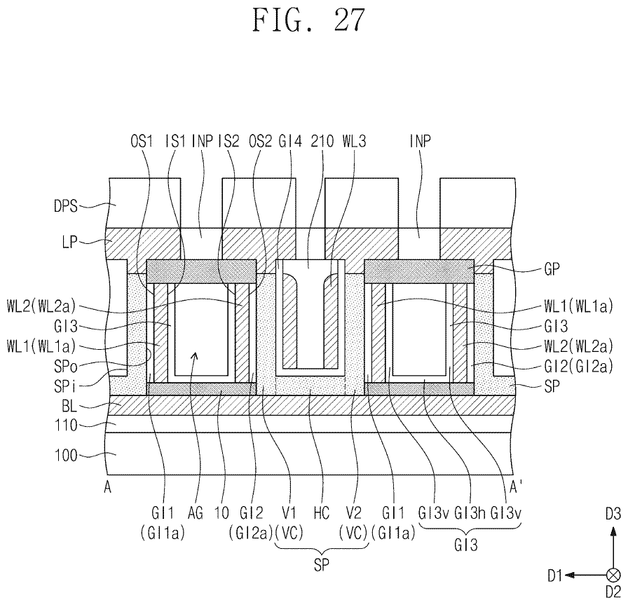

Referring to FIG. 27, a fourth gate insulating layer GI4 on the semiconductor pattern SP and a third word line WL3 on the fourth gate insulating layer GI4 may be provided. The third word lines WL3 may be spaced apart from each other in the first direction D1 with the insulating pattern 210 interposed therebetween. A first vertical portion V1 of the semiconductor pattern SP may be disposed between the first word line WL1 and the third word line WL3. A second vertical portion V2 of the semiconductor pattern SP may be disposed between the second word line WL2 and the third word line WL3. The fourth gate insulating layer GI4 may be in contact with the landing pad LP.

An air gap AG may be provided on the third gate insulating layer GI3. The air gap AG may be interposed between the vertical portions GI3v of the third gate insulating layer GI3. The air gap AG may expose the horizontal portion GI3h of the third gate insulating layer GI3.

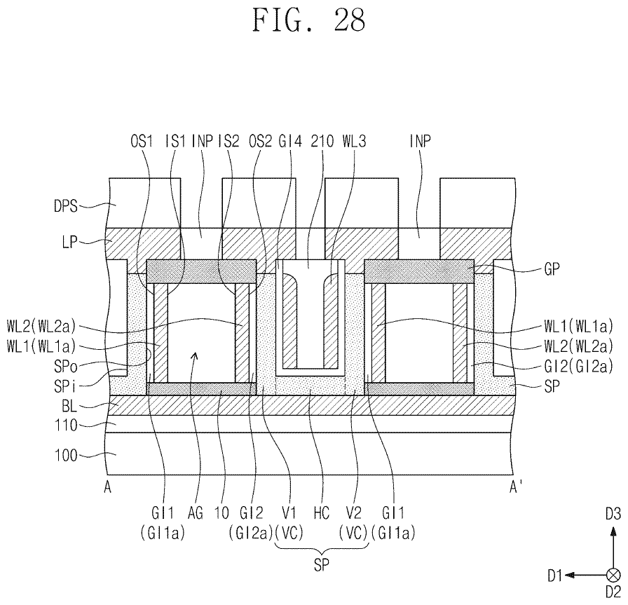

Referring to FIG. 28, a fourth gate insulating layer GI4 on the semiconductor pattern SP and a third word line WL3 on the fourth gate insulating layer GI4 may be provided. The third word lines WL3 may be spaced apart from each other in the first direction D1 with the insulating pattern 210 interposed therebetween. The first vertical portion V1 of the semiconductor pattern SP may be disposed between the first word line WL1 and the third word line WL3. The second vertical portion V2 of the semiconductor pattern SP may be disposed between the second word line WL2 and the third word line WL3. The fourth gate insulating layer GI4 may be in contact with the landing pad LP.

An air gap AG may be provided between the first word line WL1 and the second word line WL2. The air gap AG may expose the inner wall IS1 of the first word line WL1 and the inner wall IS2 of the second word line WL2. The air gap AG may expose the upper surface of the support insulating layer 10. The air gap AG may expose the lower surface of the gate capping layer GP.

In FIGS. 24 to 28, the number of word lines surrounding the channel may be increased by additionally forming the third word line WL3. Accordingly, the area of the channel capable of being controlled by the gate may be increased, thereby providing a semiconductor device with improved electrical characteristics.

In some implementations, using the disclosed structures in which the word line surrounds the side surfaces of the channel can increase the area of the channel capable of being controlled by the gate. Accordingly, a semiconductor device with the improved electrical characteristics may be provided.

In some implementations, using the disclosed concepts may reduce the electrical interference between the word lines by providing the low-k material or the air gap between the word lines. Accordingly, the electrical characteristics of the semiconductor device may be improved, and the integration of the wiring may be increased.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor device comprising:
a substrate;
a bit line extending in a first direction on the substrate;
a first word line and a second word line that extend in a second direction on the bit line, that cross the bit line, and that are spaced apart from each other in the first direction, wherein the first direction and the second direction are parallel to an upper surface of the substrate and intersect each other; and
semiconductor patterns on the bit line spaced apart from each other in the first direction, the first word line and the second word line being interposed between the semiconductor patterns,
wherein the first word line includes:
a first portion extending in the second direction, and
second portions that i) protrude from the first portion in the first direction and ii) are spaced apart from each other in the second direction,
wherein the second word line includes a first portion extending in the second direction and second portions protruding in a third direction that is opposite to the first direction, and
wherein a first semiconductor pattern of the semiconductor patterns is interposed between the second portions of the first word line, and a second semiconductor pattern of the semiconductor patterns is interposed between the second portions of the second word line.

2. The semiconductor device of claim 1, wherein each of the semiconductor patterns includes a first vertical portion and a second vertical portion facing each other in the first direction, and
wherein the first vertical portion of the first semiconductor pattern is disposed between the second portions of the first word line, and the second vertical portion of the second semiconductor pattern of the semiconductor patterns is disposed between the second portions of the second word line.

3. The semiconductor device of claim 1, further comprising:
a first gate insulating layer disposed between an outer wall of the first word line and the first semiconductor pattern of the semiconductor patterns; and
a second gate insulating layer disposed between an outer wall of the second word line and the second semiconductor pattern of the semiconductor patterns.

4. The semiconductor device of claim 3, further comprising a third gate insulating layer disposed on an inner wall of the first word line and an inner wall of the second word line.

5. The semiconductor device of claim 4, wherein the third gate insulating layer includes:
vertical portions in contact with the inner wall of the first word line and the inner wall of the second word line; and
a horizontal portion connecting the vertical portions of the third gate insulating layer.

6. The semiconductor device of claim 5, further comprising a cell insulating layer on the third gate insulating layer,
wherein the cell insulating layer is disposed between the first word line and the second word line.

7. The semiconductor device of claim 5, further comprising boundaries of the vertical portions of the third gate insulating layer define an air gap that exposes the horizontal portion of the third gate insulating layer.

8. The semiconductor device of claim 3, further comprising:
a support insulating layer in contact with an upper surface of the bit line; and
a gate capping layer,
wherein lower surfaces of the first word line, the second word line, the first gate insulating layer, and the second gate insulating layer are in contact with an upper surface of the support insulating layer, and
wherein upper surfaces of the first word line, the second word line, the first gate insulating layer, and the second gate insulating layer are in contact with a lower surface of the gate capping layer.

9. The semiconductor device of claim 8, further comprising an air gap between the first word line and the second word line,
wherein the air gap exposes inner walls of the first and second word lines and an upper surface of the support insulating layer.

10. The semiconductor device of claim 9, wherein the air gap exposes the lower surface of the gate capping layer.

11. The semiconductor device of claim 8, further comprising a cell insulating layer between the first word line and the second word line,
wherein a lower surface of the cell insulating layer is in contact with the upper surface of the support insulating layer, and an upper surface of the cell insulating layer is in contact with the lower surface of the gate capping layer.

12. A semiconductor device comprising:
a substrate;
bit lines that extend in a first direction on the substrate and that are spaced apart from each other in a second direction, wherein the first direction and the second direction are parallel to an upper surface of the substrate and intersect each other;
a first word line that crosses the bit lines and includes a first portion extending in the second direction and a second portion that i) protrudes from the first portion in the first direction and ii) is spaced apart from each other in the second direction; and
semiconductor patterns disposed on respective bit lines of the bit lines,
wherein the semiconductor patterns include first vertical portions extending in a direction perpendicular to the upper surface of the substrate, each semiconductor pattern having a respective first vertical portion,
wherein the first vertical portions of the semiconductor patterns are interposed between the second portions of the first word line, and
wherein the second portions of the first word line and the first vertical portions of the semiconductor patterns are alternately arranged in the second direction.

13. The semiconductor device of claim 12, further comprising a first gate insulating layer between the first word line and the semiconductor patterns,
wherein the first gate insulating layer is in contact with the first vertical portions of the semiconductor patterns and is in contact with an outer wall of the first word line.

14. The semiconductor device of claim 12, further comprising a second word line crossing the bit lines and spaced apart from the first word line in the first direction,
wherein the second word line includes a first portion extending in the second direction and second portions protruding from the first portion in a third direction that is opposite to the first direction and spaced apart from each other in the second direction,
wherein each of the semiconductor patterns extends in the direction perpendicular to the upper surface of the substrate,
wherein the semiconductor patterns include second vertical portions, and each second vertical portion faces a respective, first vertical portion in the first direction,
wherein the second vertical portions of the semiconductor patterns are interposed between the second portions of the second word line, and
wherein the second portions of the second word line and the second vertical portions of the semiconductor patterns are alternately arranged in the second direction.

15. The semiconductor device of claim 14, further comprising:
a first gate insulating layer between the first word line and the semiconductor patterns; and
a second gate insulating layer between the second word line and the semiconductor patterns,
wherein the first gate insulating layer is in contact with the first vertical portions of the semiconductor patterns and is in contact with an outer wall of the first word line, and
wherein the second gate insulating layer is in contact with the second vertical portions of the semiconductor patterns and is in contact with an outer wall of the second word line.

16. The semiconductor device of claim 15, further comprising third gate insulating layers in contact with an inner wall of the first word line and an inner wall of the second word line, respectively.

17. The semiconductor device of claim 15, wherein each of the semiconductor patterns includes a horizontal portion connecting the first vertical portion and the second vertical portion, and
wherein the horizontal portion of each of the semiconductor patterns is in contact with an upper surface of the bit line.

18. The semiconductor device of claim 17, further comprising:
a third gate insulating layer in contact with the first and second vertical portions of each of the semiconductor patterns and extending onto an upper surface of the horizontal portion of each of the semiconductor patterns; and
a third word line on the third gate insulating layer.

19. A semiconductor device comprising:
a substrate;
a bit line that extends in a first direction on the substrate;
a support insulating layer on the bit line;
a first word line and a second word line that cross the bit line on the support insulating layer;
semiconductor patterns disposed on the bit line and spaced apart from each other in the first direction, the support insulating layer, the first word line, and the second word line being interposed between the semiconductor patterns;
a first gate insulating layer between a first semiconductor pattern and an outer wall of the first word line; and
a second gate insulating layer between a second semiconductor pattern and an outer wall of the second word line,
wherein the first word line includes a first portion that i) extends in a second direction parallel to an upper surface of the substrate and ii) intersects the first direction, and second portions protruding in the first direction,
wherein the second word line includes a first portion extending in the second direction and second portions protruding in a third direction that is opposite to the first direction,
wherein the first semiconductor pattern is disposed between second portions of the first word line, and
wherein the second semiconductor pattern is disposed between second portions of the second word line.

20. The semiconductor device of claim 19, further comprising:
a gate capping layer in contact with the first and second word lines and upper surfaces of the first and second gate insulating layers;
a landing pad connected to the semiconductor patterns; and
a data storage pattern connected to the landing pad.
